(19) United States
(12) Patent Application Publication
(10) Pub. No.: US 2023/0325644 A1
(43) Pub. Date: Oct. 12, 2023

(54) Implementation Aspects Of Predictive Residual Encoding In Neural Networks Compression

(71) Applicant: Nokia Technologies Oy, Espoo (FI)

(72) Inventors: Homayun AFRABANDPEY, Espoo (FI); Hamed REZAZADEGAN TAVAKOLI, Espoo (FI); Francesco Cricri, Tampere (FI); Honglei Zhang, Tampere (FI); Goutham Rangu, Tampere (FI); Emre Baris Aksu, Tampere (FI)

(21) Appl. No.: 18/133,031

(22) Filed: Apr. 11, 2023

Related U.S. Application Data
(60) Provisional application No. 63/329,643, filed on Apr. 11, 2022.

(51) Int. Cl. G06N 3/0495; G06N 3/08; G06N 3/0455

(52) U.S. Cl. CPC G06N 3/0495; G06N 3/08; G06N 3/0455

(57) ABSTRACT

An apparatus comprising: at least one processor; and at least one memory storing instructions that, when executed by the at least one processor, cause the apparatus at least to: maintain a first parameter update tree that tracks residuals of weight updates of a machine learning model; maintain a second parameter update tree that tracks the weight updates of the machine learning model; pass the first parameter update tree and the residuals to an encoder; receive a first bitstream generated for the residuals from the encoder; pass the second parameter update tree and the weight updates to the encoder; receive a second bitstream generated for the weight updates from the encoder; and determine whether to signal to a decoder the first bitstream generated for the residuals or the second bitstream generated for the weight updates.

### RELATED APPLICATION

This application claims priority to U.S. Provisional Application No. 63/329,643, filed Apr. 11, 2022, which is hereby incorporated by reference in its entirety.

### TECHNICAL FIELD

The examples and non-limiting embodiments relate generally to multimedia transport and machine learning and, more particularly, to implementation aspects of predictive residual encoding in neural network compression.

### BACKGROUND

It is known to perform data compression and decoding in a multimedia system.

### SUMMARY

In accordance with an aspect, an apparatus includes: at least one processor; and at least one memory storing instructions that, when executed by the at least one processor, cause the apparatus at least to: maintain a first parameter update tree that tracks residuals of weight updates of, a machine learning model; maintain a second parameter update tree that tracks the weight updates of the machine learning model; pass the first parameter update tree and the residuals to an encoder; receive a first bitstream generated for the residuals from the encoder; pass the second parameter update tree and the weight updates to the encoder; receive a second bitstream generated for the weight updates from the encoder; and determine whether to signal to a decoder the first bitstream generated for the residuals or the second bitstream generated for the weight updates.

In accordance with an aspect, an apparatus includes: at least one processor; and at least one memory storing instructions that, when executed by the at least one processor, cause the apparatus at least to: maintain a first parameter update tree that tracks residuals of weight updates of a machine learning model; maintain a second parameter update tree that tracks the weight updates of the machine learning model; receive a bitstream, the bitstream comprising encoded residuals or encoded weight updates; update the first parameter update tree that tracks the residuals, in response to the bitstream comprising the encoded residuals; and update the second parameter update tree that tracks the weight updates, in response to the bitstream comprising the encoded weight updates.

In accordance with an aspect, a method includes: maintaining a first parameter update tree that tracks residuals of weight updates of a machine learning model; maintaining a second parameter update tree that tracks the weight updates of the machine learning model; passing the first parameter update tree and the residuals to an encoder; receiving a first bitstream generated for the residuals from the encoder; passing the second parameter update tree and the weight updates to the encoder; receiving a second bitstream generated for the weight updates from the encoder; and determining whether to signal to a decoder the first bitstream generated for the residuals or the second bitstream generated for the weight updates.

### BRIEF DESCRIPTION OF THE DRAWINGS

The foregoing aspects and other features are explained in the following description, taken in connection with the accompanying drawings, wherein:

FIG. 1 shows schematically an electronic device employing embodiments of the examples described herein.

FIG. 2 shows schematically a user equipment suitable for employing embodiments of the examples described herein.

FIG. 3 further shows schematically electronic devices employing embodiments of the examples described herein connected using wireless and wired network connections.

FIG. 4 shows schematically a block chart of an encoder used for data compression on a general level.

FIG. 5 shows that context model selection for encoding of a value x depends on a corresponding (co-located) value c in the same layer of a previous update.

FIG. 6 shows updating a node of a PUT by attaching child nodes.

FIG. 7 is a code snippet for calling a PRE decoder which computes weight updates of each parameter given its residual.

FIG. 8 is a flowchart of a procedure of computing the weight update value of a skipped parameter when the encoder is communicated the encoded residuals.

FIG. 9 is a code snippet of an implementation of the process shown in FIG. 8.

FIG. 10 is an example apparatus configured to implement aspects of predictive residual encoding in neural network compression, based on the examples described herein.

FIG. 11 is an example method to implement aspects of predictive residual encoding in neural network compression, based on the examples described herein.

FIG. 12 is an example method to implement aspects of predictive residual encoding in neural network compression, based on the examples described herein.

FIG. 13 is an example method to implement aspects of predictive residual encoding in neural network compression, based on the examples described herein.

### DETAILED DESCRIPTION OF EXAMPLE EMBODIMENTS

Described herein is a practical approach to integrate predictive residual encoding (PRE) with parameter update tree (PUT) and temporal context adaptation (TCA). The models described herein may be used to perform any task, such as data compression, data decompression, video compression, video decompression, image or video classification, object classification, object detection, object tracking, speech recognition, language translation, music transcription, etc.

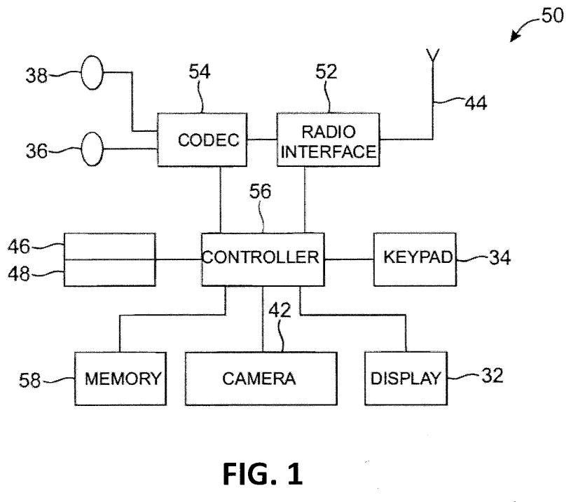

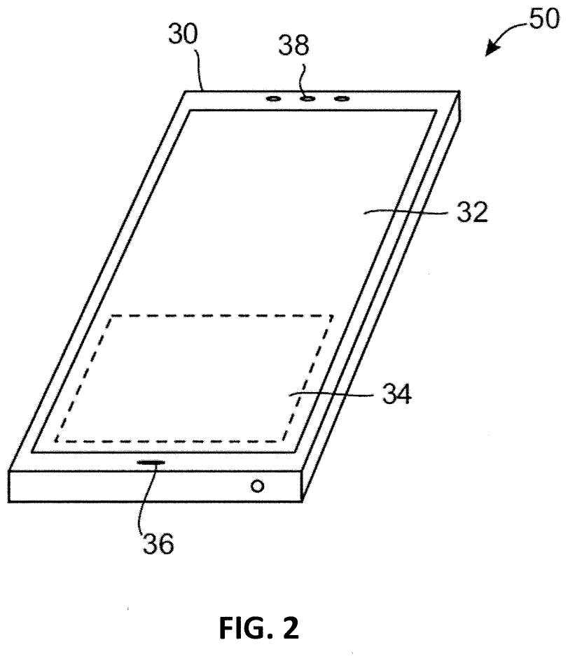

The following describes in detail a suitable apparatus and possible mechanisms to implement aspects of predictive residual encoding in neural network compression. In this regard reference is first made to FIG. 1 and FIG. 2, where FIG. 1 shows an example block diagram of an apparatus 50. The apparatus may be an Internet of Things (IoT) apparatus configured to perform various functions, such as for example, gathering information by one or more sensors, receiving or transmitting information, analyzing information gathered or received by the apparatus, or the like. The apparatus may comprise a neural network weight update coding system, which may incorporate a codec. FIG. 2 shows a layout of an apparatus according to an example embodiment. The elements of FIG. 1 and FIG. 2 are explained next.

The electronic device 50 may for example be a mobile terminal or user equipment of a wireless communication system, a sensor device, a tag, or other lower power device. However, it would be appreciated that embodiments of the examples described herein may be implemented within any electronic device or apparatus which may process data by neural networks.

The apparatus 50 may comprise a housing 30 for incorporating and protecting the device. The apparatus 50 further may comprise a display 32 in the form of a liquid crystal display. In other embodiments of the examples described herein the display may be any suitable display technology suitable to display an image or video. The apparatus 50 may further comprise a keypad 34. In other embodiments of the examples described herein any suitable data or user interface mechanism may be employed. For example the user interface may be implemented as a virtual keyboard or data entry system as part of a touch-sensitive display.

The apparatus may comprise a microphone 36 or any suitable audio input which may be a digital or analog signal input. The apparatus 50 may further comprise an audio output device which in embodiments of the examples described herein may be any one of: an earpiece 38, speaker, or an analog audio or digital audio output connection. The apparatus 50 may also comprise a battery (or in other embodiments of the examples described herein the device may be powered by any suitable mobile energy device such as solar cell, fuel cell or clockwork generator). The apparatus may further comprise a camera capable of recording or capturing images and/or video. The apparatus 50 may further comprise an infrared port for short range line of sight communication to other devices. In other embodiments the apparatus 50 may further comprise any suitable short range communication solution such as for example a Bluetooth wireless connection or a USB/firewire wired connection.

The apparatus 50 may comprise a controller 56, processor or processor circuitry for controlling the apparatus 50. The controller 56 may be connected to memory 58 which in embodiments of the examples described herein may store both data in the form of image and audio data and/or may also store instructions for implementation on the controller 56. The controller 56 may further be connected to codec circuitry 54 suitable for carrying out coding/compression of neural network weight updates and/or decoding of audio and/or video data or assisting in coding and/or decoding carried out by the controller.

The apparatus 50 may further comprise a card reader 48 and a smart card 46, for example a UICC and UICC reader for providing user information and being suitable for providing authentication information for authentication and authorization of the user at a network.

The apparatus 50 may comprise radio interface circuitry 52 connected to the controller and suitable for generating wireless communication signals for example for communication with a cellular communications network, a wireless communications system or a wireless local area network. The apparatus 50 may further comprise an antenna 44 connected to the radio interface circuitry 52 for transmitting radio frequency signals generated at the radio interface circuitry 52 to other apparatus(es) and/or for receiving radio frequency signals from other apparatus(es).

The apparatus 50 may comprise a camera capable of recording or detecting individual frames which are then passed to the codec 54 or the controller for processing. The apparatus may receive the video image data or machine learning data for processing from another device prior to transmission and/or storage. The apparatus 50 may also receive either wirelessly or by a wired connection the image for coding/decoding. The structural elements of apparatus 50 described above represent examples of means for performing a corresponding function.

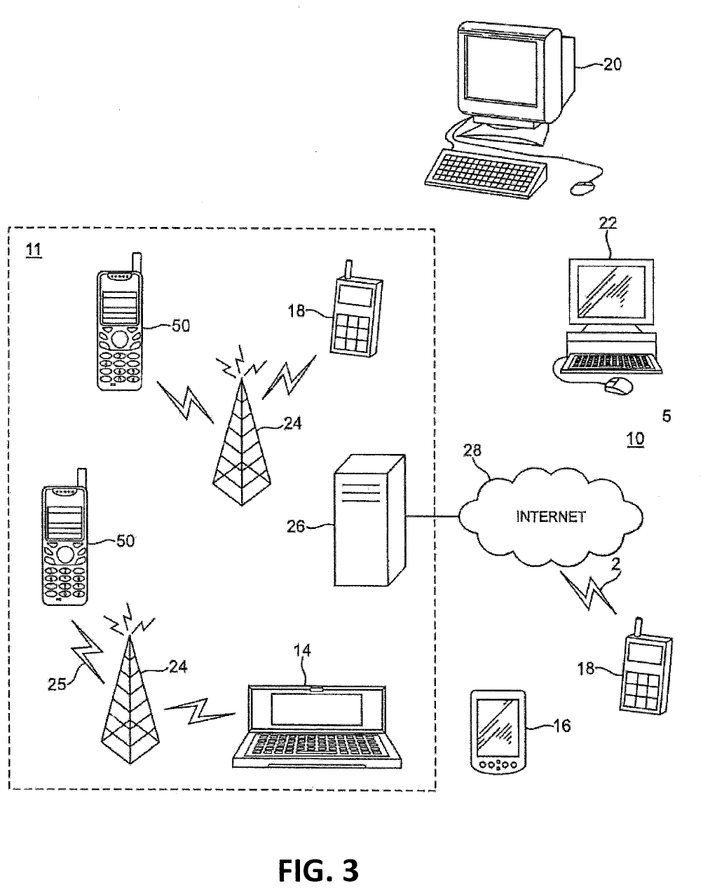

With respect to FIG. 3, an example of a system within which embodiments of the examples described herein can be utilized is shown. The system 10 comprises multiple communication devices which can communicate through one or more networks. The system 10 may comprise any combination of wired or wireless networks including, but not limited to a wireless cellular telephone network (such as a GSM, UMTS, CDMA, LTE, 4G, 5G network etc.), a wireless local area network (WLAN) such as defined by any of the IEEE 802.x standards, a Bluetooth personal area network, an Ethernet local area network, a token ring local area network, a wide area network, and the Internet.

The system 10 may include both wired and wireless communication devices and/or apparatus 50 suitable for implementing embodiments of the examples described herein.

For example, the system shown in FIG. 3 shows a mobile telephone network 11 and a representation of the internet 28. Connectivity to the internet 28 may include, but is not limited to, long range wireless connections, short range wireless connections, and various wired connections including, but not limited to, telephone lines, cable lines, power lines, and similar communication pathways.

The example communication devices shown in the system 10 may include, but are not limited to, an electronic device or apparatus 50, a combination of a personal digital assistant (PDA) and a mobile telephone 14, a PDA 16, an integrated messaging device (IMD) 18, a desktop computer 20, a notebook computer 22. The apparatus 50 may be stationary or mobile when carried by an individual who is moving. The apparatus 50 may also be located in a mode of transport including, but not limited to, a car, a truck, a taxi, a bus, a train, a boat, an airplane, a bicycle, a motorcycle or any similar suitable mode of transport, or a head mounted display (HMD).

The embodiments may also be implemented in a set-top box; i.e. a digital TV receiver, which may/may not have a display or wireless capabilities, in tablets or (laptop) personal computers (PC), which have hardware and/or software to process neural network data, in various operating systems, and in chipsets, processors, DSPs and/or embedded systems offering hardware/software based coding.

Some or further apparatus may send and receive calls and messages and communicate with service providers through a′ wireless connection 25 to a base station 24. The base station 24 may be connected to a network server 26 that allows communication between the mobile telephone network 11 and the internet 28. The system may include additional communication devices and communication devices of various types.

The communication devices may communicate using various transmission technologies including, but not limited to, code division multiple access (CDMA), global systems for mobile, communications (GSM), universal mobile telecommunications system (UMTS), time divisional multiple access (TDMA), frequency division multiple access (FDMA), transmission control protocol-internet protocol (TCP-IP), short messaging service (SMS), multimedia messaging service (MMS), email, instant messaging service (IMS), Bluetooth, IEEE 802.11, 3GPP Narrowband IoT and any similar wireless communication technology. A communications device involved in implementing various embodiments of the examples described herein may communicate using various media including, but not limited to, radio, infrared, laser, cable connections, and any suitable connection.

In telecommunications and data networks, a channel may refer either to a physical channel or to a logical channel. A physical channel may refer to a physical transmission medium such as a wire, whereas a logical channel may refer to a logical connection over a multiplexed medium, capable of conveying several logical channels. A channel may be used for conveying an information signal, for example a bitstream, from one or several senders (or transmitters) to one or several receivers.

The embodiments may also be implemented in so-called IoT devices. The Internet of Things (IoT) may be defined, for example, as an interconnection of uniquely identifiable embedded computing devices within the existing Internet infrastructure. The convergence of various technologies has and may enable many fields of embedded systems, such as wireless sensor networks, control systems, home/building automation, etc. to be included in the Internet of Things (IoT). In order to utilize the Internet IoT devices are provided with an IP address as a unique identifier. IoT devices may be provided with a radio transmitter, such as a WLAN or Bluetooth transmitter or a RFID tag. Alternatively, IoT devices may have access to an IP-based network via a wired network, such as an Ethernet-based network or a power-line connection (PLC).

One important application where predictive residual encoding is important, is the use case of neural network based codecs, such as neural network based video codecs. Video codecs may use one or more neural networks. In a first case, the video codec may be a conventional video codec such as the Versatile Video Codec (VVC/H.266) that has been modified to include one or more neural networks. Examples of these neural networks are:
1. a neural network filter to be used as one of the in-loop filters of VVC
2. a neural network filter to replace one or more of the in-loop filter(s) of VVC
3. a neural network filter to be used as a post-processing filter
4. a neural network to be used for performing intra-frame prediction
5. a neural network to be used for performing inter-frame prediction.

In a second case, which is usually referred to as an end-to-end learned video codec, the video codec may comprise a neural network that transforms the input data into a more compressible representation. The new representation may be quantized, lossless compressed, then lossless decompressed, dequantized, and then another neural network may transform its input into reconstructed or decoded data.

In both of the above two cases, there may be one or more neural networks at the decoder-side, and consider the example of one neural network filter. The encoder may finetune the neural network filter by using the ground-truth data which is available at encoder side (the uncompressed data). Finetuning may be performed in order to improve the neural network filter when applied to the current input data, such as to one or more video frames. Finetuning may comprise running one or more optimization iterations on some or all the learnable weights of the neural network filter. An optimization iteration may comprise computing gradients of a loss function with respect to some or all the learnable weights of the neural network filter, for example by using the backpropagation algorithm, and then updating the some or all learnable weights by using an optimizer, such as the stochastic gradient descent optimizer. The loss function may comprise one or more loss terms. One example loss term may be the mean squared error (MSE). Other distortion metrics may be used as the loss terms. The loss function may be computed by providing one or more data to the input of the neural network filter, obtaining one or more corresponding outputs from the neural network filter, and computing a loss term by using the one or more outputs from the neural network filter and one or more ground-truth data. The difference between the weights of the finetuned neural network and the weights of the neural network before finetuning is referred to as the weight-update. This weight-update needs to be encoded, provided to the decoder side together with the encoded video data, and used at the decoder side for updating the neural network filter. The updated neural network filter is then used as part of the video decoding process or as part of the video post-processing process. It is desirable to encode the weight-update such that it requires a small number of bits. Thus, the examples described herein consider also this use case of neural network based codecs as a potential application of the compression of weight-updates.

In further description of the neural network based codec use case, an MPEG-2 transport stream (TS), specified in ISO/IEC 13818-1 or equivalently in ITU-T Recommendation H.222.0, is a format for carrying audio, video, and other media as well as program metadata or other metadata, in a multiplexed stream. A packet identifier (PID) is used to identify an elementary stream (a.k.a. packetized elementary stream) within the TS. Hence, a logical channel within an MPEG-2 TS may be considered to correspond to a specific PID value.

Available media file format standards include ISO base media file format (ISO/IEC 14496-12, which may be abbreviated ISOBMFF) and file format for NAL unit structured video (ISO/IEC 14496-15), which derives from the ISOBMFF.

A video codec consists of an encoder that transforms the input video into a compressed representation suited for storage/transmission and a decoder that can uncompress the compressed video representation back into a viewable form. A video encoder and/or a video decoder may also be separate from each other, i.e. need not form a codec. Typically the encoder discards some information in the original video sequence in order to represent the video in a more compact form (that is, at lower bitrate).

Typical hybrid video encoders, for example many encoder implementations of ITU-T H.263 and H.264, encode the video information in two phases. Firstly pixel values in a certain picture area (or “block”) are predicted for example by motion compensation means (finding and indicating an area in one of the previously coded video frames that corresponds closely to the block being coded) or by spatial means (using the pixel values around the block to be coded in a specified manner). Secondly the prediction error, i.e. the difference between the predicted block of pixels and the original block of pixels, is coded. This is typically done by transforming the difference in pixel values using a specified transform (e.g. Discrete Cosine Transform (DCT) or a variant of it), quantizing the coefficients and entropy coding the quantized coefficients. By varying the fidelity of the quantization process, encoder can control the balance between the accuracy of the pixel representation (picture quality) and size of the resulting coded video representation (file size or transmission bitrate).

In temporal prediction, the sources of prediction are previously decoded pictures (a.k.a. reference pictures). In intra block copy (IBC; a.k.a. intra-block-copy prediction and current picture referencing), prediction is applied similarly to temporal prediction but the reference picture is the current picture and only previously decoded samples can be referred in the prediction process. Inter-layer or inter-view prediction may be applied similarly to temporal prediction, but the reference picture is a decoded picture from another scalable layer or from another view, respectively. In some cases, inter prediction may refer to temporal prediction only, while in other cases inter prediction may refer collectively to temporal prediction and any of intra block copy, inter-layer prediction, and inter-view prediction provided that they are performed with the same or similar process as temporal prediction. Inter prediction or temporal prediction may sometimes be referred to as motion compensation or motion-compensated prediction.

Inter prediction, which may also be referred to as temporal prediction, motion compensation, or motion-compensated prediction, reduces temporal redundancy. In inter prediction the sources of prediction are previously decoded pictures. Intra prediction utilizes the fact that adjacent pixels within the same picture are likely to be correlated. Intra prediction can be performed in the spatial or transform domain, i.e., either sample values or transform coefficients can be predicted. Intra prediction is typically exploited in intra coding, where no inter prediction is applied.

One outcome of the coding procedure is a set of coding parameters, such as motion vectors and quantized transform coefficients. Many parameters can be entropy-coded more efficiently if they are predicted first from spatially or temporally neighboring parameters. For example, a motion vector may be predicted from spatially adjacent motion vectors and only the difference relative to the motion vector predictor may be coded. Prediction of coding parameters and intra prediction may be collectively referred to as in-picture prediction.

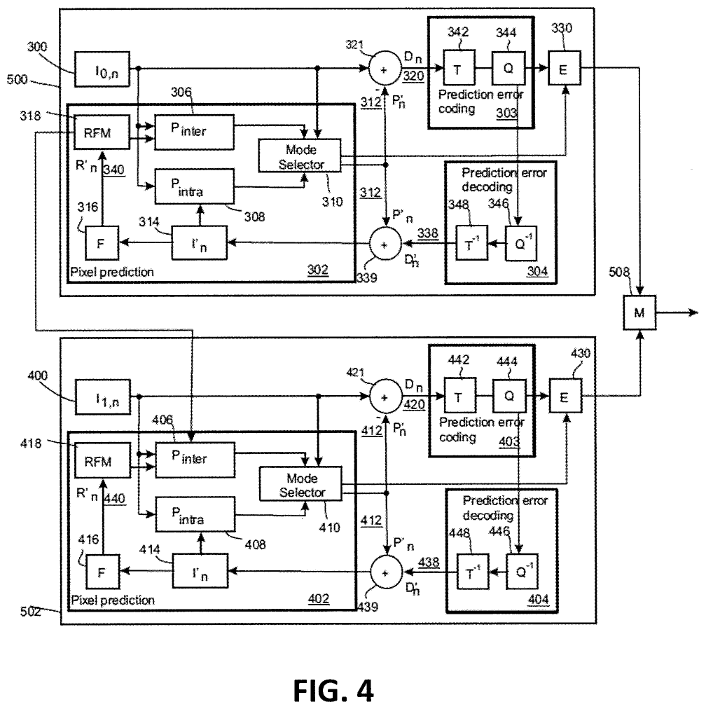

FIG. 4 shows a block diagram of a general structure of a video encoder. FIG. 4 presents an encoder for two layers, but it would be appreciated that presented encoder could be similarly extended to encode more than two layers. FIG. 4 illustrates a video encoder comprising a first encoder section 500 for a base layer and a second encoder section 502 for an enhancement layer. Each of the first encoder section 500 and the second encoder section 502 may comprise similar elements for encoding incoming pictures. The encoder sections 500, 502 may comprise a pixel predictor 302, 402, prediction error encoder 303, 403 and prediction error decoder 304, 404. FIG. 4 also shows an embodiment of the pixel predictor 302, 402 as comprising an inter-predictor 306, 406 (Pᵢₙₜₑᵣ), an intra-predictor 308, 408 (Pᵢₙₜᵣₐ), a mode selector 310, 410, a filter 316, 416 (F), and a reference frame memory 318, 418 (RFM). The pixel predictor 302 of the first encoder section 500 receives 300 base layer images (I_{0,n}) of a video stream to be encoded at both the inter-predictor 306 (which determines the difference between the image and a motion compensated reference frame 318) and the intra-predictor 308 (which determines a prediction for an image block based only on the already processed parts of the current frame or picture). The output of both the inter-predictor and the intra-predictor are passed to the mode selector 310. The intra-predictor 308 may have more than one intra-prediction modes. Hence, each mode may perform the intra-prediction and provide the predicted signal to the mode selector 310. The mode selector 310 also receives a copy of the base layer picture 300. Correspondingly, the pixel predictor 402 of the second encoder section 502 receives 400 enhancement layer images (I_{1,n}) of a video stream to be encoded at both the inter-predictor 406 (which determines the difference between the image and a motion compensated reference frame 418) and the intra-predictor 408 (which determines a prediction for an image block based only on the already processed parts of the current frame or picture). The output of both the inter-predictor and the intra-predictor are passed to the mode selector 410. The intra-predictor 408 may have more than one intra-prediction modes. Hence, each mode may perform the intra-prediction and provide the predicted signal to the mode selector 410. The mode selector 410 also receives a copy of the enhancement layer picture 400.

Depending on which encoding mode is selected to encode the current block, the output of the inter-predictor 306, 406 or the output of one of the optional intra-predictor modes or the output of a surface encoder within the mode selector is passed to the output of the mode selector 310, 410. The output of the mode selector is passed to a first summing device 321, 421. The first summing device may subtract the output of the pixel predictor 302, 402 from the base layer picture 300/enhancement layer picture 400 to produce a first prediction error signal 320, 420 (Dₙ) which is input to the prediction error encoder 303, 403.

The pixel predictor 302, 402 further receives from a preliminary reconstructor 339, 439 the combination of the prediction representation of the image block 312, 412 (P′ₙ) and the output 338, 438 (D′ₙ) of the prediction error decoder 304, 404. The preliminary reconstructed image 314, 414 (I′ₙ) may be passed to the intra-predictor 308, 408 and to the filter 316, 416. The filter 316, 416 receiving the preliminary representation may filter the preliminary representation and output a final reconstructed image 340, 440 (R′ₙ) which may be saved in a reference frame memory 318, 418. The reference frame memory 318 may be connected to the inter-predictor 306 to be used as the reference image against which a future base layer picture 300 is compared in inter-prediction operations. Subject to the base layer being selected and indicated to be the source for inter-layer sample prediction and/or inter-layer motion information prediction of the enhancement layer according to some embodiments, the reference frame memory 318 may also be connected to the inter-predictor 406 to be used as the reference image against which a future enhancement layer picture 400 is compared in inter-prediction operations. Moreover, the reference frame memory 418 may be connected to the inter-predictor 406 to be used as the reference image against which a future enhancement layer picture 400 is compared in inter-prediction operations.

Filtering parameters from the filter 316 of the first encoder section 500 may be provided to the second encoder section 502 subject to the base layer being selected and indicated to be the source for predicting the filtering parameters of the enhancement layer according to some embodiments.

The prediction error encoder 303, 403 comprises a transform unit 342, 442 (T) and a quantizer 344, 444 (Q). The transform unit 342, 442 transforms the first prediction error signal 320, 420 to a transform domain. The transform is, for example, the DCT transform. The quantizer 344, 444 quantizes the transform domain signal, e.g. the DCT coefficients, to form quantized coefficients.

The prediction error decoder 304, 404 receives the output from the prediction error encoder 303, 403 and performs the opposite processes of the prediction error encoder 303, 403 to produce a decoded prediction error signal 338, 438 which, when combined with the prediction representation of the image block 312, 412 at the second summing device 339, 439, produces the preliminary reconstructed image 314, 414. The prediction error decoder 304, 404 may be considered to comprise a dequantizer 346, 446 (Q⁻¹), which dequantizes the quantized coefficient values, e.g. DCT coefficients, to reconstruct the transform signal and an inverse transformation unit 348, 448 (T⁻¹), which performs the inverse transformation to the reconstructed transform signal wherein the output of the inverse transformation unit 348, 448 contains reconstructed block(s). The prediction error decoder may also comprise a block filter which may filter the reconstructed block(s) according to further decoded information and filter parameters.

The entropy encoder 330, 430 (E) receives the output of the prediction error encoder 303, 403 and may perform a suitable entropy encoding/variable length encoding on the signal to provide error detection and correction capability. The outputs of the entropy encoders 330, 430 may be inserted into a bitstream e.g. by a multiplexer 508 (M).

MPEG NNC has issued a call for proposal (CfP) for incremental compression of neural networks (NN), which includes two use cases: (i) federated inference (FI), and (ii) federated learning (FL). In FI, a client which has no access to the test data trains a NN iteratively and incrementally where in each iteration the obtained model is sent for a server with access to the test data to be evaluated. In the FL scenario, two clients and a server jointly train a model. To improve communication efficiency, it is assumed that entities, i.e., the clients and the server, only communicate the updates to the weights rather than the full model. The goal of the CfP is to develop a model compression framework to reduce communication overhead between the clients and the server such that the model that is trained jointly and incrementally is as accurate as possible with the least communication load. Among the adopted technologies are parameter update tree (PUT) and temporal context adaptation (TCA), both of which are elements of an encoding technique called DeepCABAC.

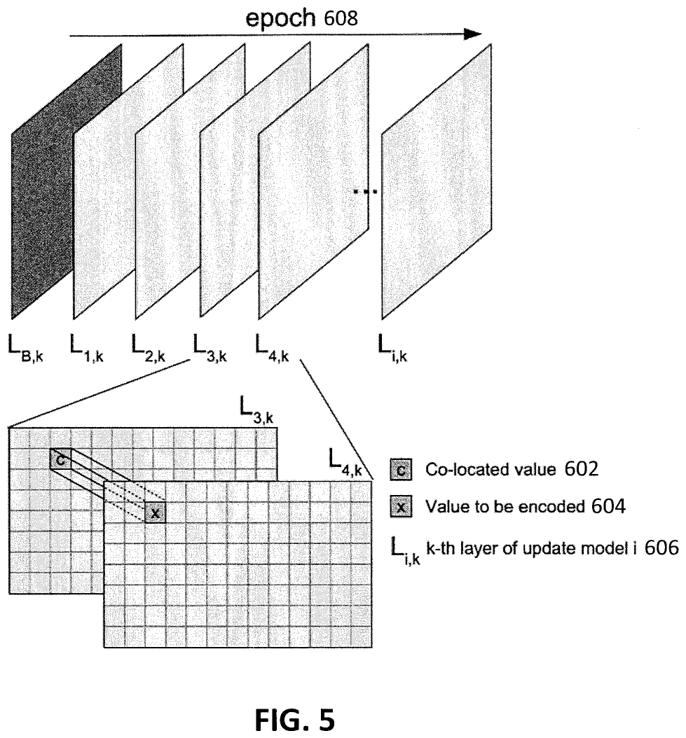

DeepCABAC is a descendant of CABAC. In both of these technologies, there exist a context modelling step where a binary probability model is assigned to each binarized input called a bin (also known as context model). Context models are updated on-the-fly using local statistics of the data. In TCA, to improve the efficiency of the encoding pipeline, context model selection is done based on temporal dependencies between inputs. Mapping this to the problem at hand, i.e., incremental compression of a NN, the inputs are weight updates of a NN model. In TCA, as shown in FIG. 5, context model selection for encoding of a value x (604) depends on a corresponding (co-located) value c (602) in the same layer (606) of the previous update. An update to a layer 606 is made within each epoch 608.

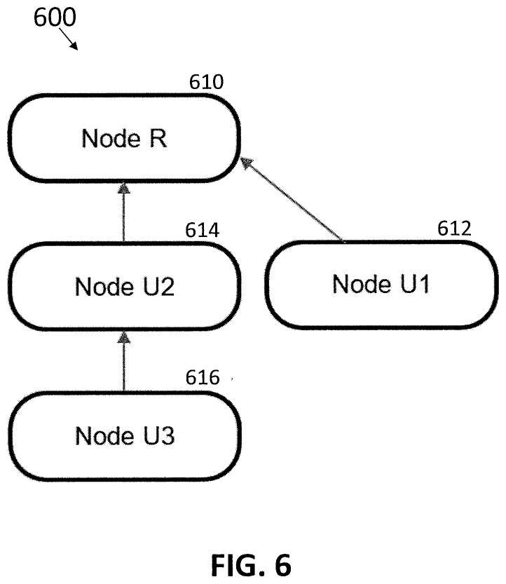

This temporal dependency necessitates keeping track of the update procedure for each parameter. For this, PUT is suggested which represents incremental updates as a tree structure. Each parameter of a model is associated with a tree. Given a particular parameter and its PUT, the parameter's base value is placed in the root node of the PUT. An incremental update of a parameter corresponds to a child node attached to the root node. Any node of the PUT may further be updated by attaching child nodes in the same manner. An example is given in FIG. 6 where R is the root node (610) representing one parameter of the base model 600.

Nodes U1 (612) and U2 (614) describe updates to node R (610), and node U3 (616) describes an update of node U2 (614). In a distributed scenario, each device (server or client) maintains update trees for the parameters of the model. In order to transmit a particular update from one device to another, only the corresponding update along with a unique identifier of its parent node needs to be transmitted. For example, consider a client and a server that both have node R 610 (as in FIG. 6) available. Assume, the client creates update U2 614 and wants to make it available to the server. For this it sends U2 614 along with the parent identifier of R 610 to the server. The server searches for the parent identifier in its version of the tree and appends U2 614 as a child node of the parent node (which is R 610 in this case). Now, the server and client both have a tree available with R 610 as root node and U2 614 as a child node of R 610. Updating of the PUT tree is done in the decoder side.

To improve the efficiency of the communication, the PUT does not communicate a parameter without any update, i.e., if all elements of the update for a parameter are zero, the parameter will not be communicated and hence the tree will not be updated for that parameter. This is called parameter skipping.

U.S. provisional application No. 63/173,583, filed by Applicant of the herein described method, describes a predictive residual coding technique called PRE to obtain efficient communication. The idea in PRE is to communicate the residuals of the weight updates, i.e., the difference between consecutive weight updates for each parameter, whenever it is beneficial. In other words, in each communication round, both the residuals and the weight updates are encoded for each single parameter of the NN model, and the one that generates the smaller bitstream is communicated. Similar to TCA, this technique also requires keeping track of the history of the parameters' weight updates both in the encoder side and in the decoder side. For this, two lists are defined; one contains the weight updates of the parameters in previous rounds in the encoder side and the other one for the decoder side.

Running PRE in conjunction with TCA and PUT entails the following challenges (1-3 immediately following):
1. Residuals are computed from consecutive weight updates, while weight updates are computed from consecutive weights. This means that the system cannot adopt PUTs defined for weight updates to be used for residuals.
2. According to the PUT parameter skipping procedure, if the weight update of a layer of the NN is a tensor/matrix of all zeros, that will be skipped and not communicated. Since residuals and weight updates have different bases, it is possible that parameter skipping of PUT skips different parameters for them. This in turn, results in a different update to the PUT tree.
3. As mentioned earlier, updating of the PUT tree is done in the decoder side. Assume in the encoder side, PRE decides to communicate the encoded weight updates because they provide smaller bitstream sizes. The decoder does not have access to the residuals as they are not communicated. Then the technical problem is how to update the PUT for the residuals in the decoder side. This also holds for the weight updates when PRE communicates encoded residuals.

Described herein are practical solutions to each of the above mentioned problems.

Described and provided in this implementation patent is a practical approach to integrate PRE with PUT and TCA. This includes solutions for the challenges mentioned herein. The approach includes modifications in both the encoder-side and the decoder-side such that residuals have their own PUT trees synched with PUT trees of weight updates.

The first step to integrate PRE with TCA and PUT is to define a separate PUT tree corresponding to each of the parameters' residual. This means that there are two PUT trees in the encoder side; one that keeps track of the changes to the weight updates and the other for residuals. These two lists are named approx_param_base and approx_resid_base. In order to encode a parameter (weight update or residual), DeepCABAC requires the value of the parameter and its base value, i.e., the previous value of the parameter that is kept in the PUT tree. PRE, once passes the approx_resid_base together with the residuals of the parameters to the DeepCABAC and receives the bitstream generated for the residuals of the parameters. Then it passes the approx_param_base together with the weight updates of the parameters and receives the bitstream. Finally, it compares the sizes of the bitstreams and communicates the one with smaller size. In order to signal the selected bitstream to the decoder, a flag mps_pre_flag is defined which is equal to 1 if PRE decided to communicate the encoded residuals and 0 otherwise. In the decoder side, the data structure generated by decoding the bitstream has a flag called pre_flag_model set to 1 if mps_pre_flag is 1 and 0 otherwise.

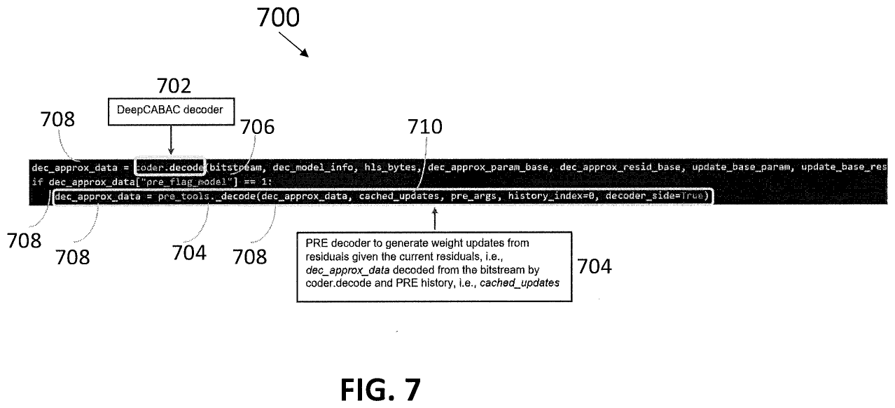

With reference to FIG. 7, in the decoder side, the bitstream is decoded by the DeepCABAC decoder 702. Via pre_flag_model 706 it is known if the decoded values are related to the residuals or the weight update. In any case, the PUT trees of the residuals need to be updated as do the weight updates. If the bitstream of the residuals is communicated, the PUT trees of the residuals are updated accordingly in the decoder side. To update the PUT trees of the weight updates, the values of the weight updates are required. To do so, the PRE decoder 704 is called which computes the weight updates of each parameter given its residual. This is shown in the code snippet shown in FIG. 7. The PRE decoder 704 is used to generate weight updates from residuals given the current residuals, i.e., dec_approx_data 708 decoded from the bitstream by coder.decode 702 and PRE history, i.e., cached updates 710, which contains the previous rounds' weight updates. Note that in round 0, only encoded weight updates are communicated since computing residuals is not possible due to lack of history.

On the other hand, if PRE communicates the encoded weight updates, the PUT trees of the weight updates are updated in the decoder side. To update the PUT trees of the residuals, it is necessary to first have access to the residuals. For this, the PRE encoder is called in the decoder side to compute residuals of the weight updates given the weight updates of the current epoch and the weight update of the previous epoch which is saved in the PRE cache.

Another issue that arises in updating the PUT trees in the decoder side is that the parameter skipping of the PRE could result in different skipped parameters for residuals and the weight updates. However, to synch the PUT trees of the weight updates and the residuals, it is necessary to have access to all residuals and weight updates in the decoder side and then decide which one is to be skipped and does not require an update of the PUT tree. This is challenging because when the PRE encoder communicates the bitstream of weight updates and PUT skips a particular parameter in this bitstream, in the decoder side it is not evident if the encoder has communicated the residuals, whether the PUT skips the same parameter or not. To solve this issue, the PUT tree of the residuals is updated manually when the PRE encoder decides to communicate the bitstream generated from weight updates and vice versa. In other words, the parameter skipping procedure of the PUT is simulated in the decoder side. Now, assume the PRE communicates the bitstream of the residuals and a parameter x is skipped because there is no nonzero element in its residual. In the decoder side, it is first checked if such parameter exists in the decoded bitstream (note that access to the full list of parameters is available in the decoder side). If not, it means that the residual of this parameter is all zero. To construct the weight update of this parameter, it is first checked if the parameter exist in the weight updates of the previous round or not. If not, it means that the weight update of this parameter in the previous round was skipped which in turn entails that it was all zero. Then, since the weight update corresponding to the parameter x in the previous round was all zero and the residual of this same parameter in the current round is also all zero, it is concluded that the weight update of this parameter in the current round is also all zero. If, on the other hand, the parameter exists in the weight update list of the previous round, since the current round's residual is all zero, the value of the weight update of this parameter in the current round is equal to the value of the weight update of the previous round.

When the bitstream contains encoded weight updates, by calling the deepCABAC decoder, the bitstream is decoded and weight updates are calculated. Right after calculating the weight updates in the deepCABAC decoder, the PUT of the weight updates is also updated inside the deepCABAC decoder. However, PUT of the residuals is not possible to be updated since the residuals are still not inside the deepCABAC decoder. Then after going out of the deepCABAC decoder the PUT of the residuals needs to be update manually, meaning that it is necessary to first call the PRE encoder to calculate the residuals of the weight update (where the PRE encoder requires one weight update of the current epoch and exactly the previous epoch's weight updates saved in the cache) and then update the PUT. So, by manually, it is meant that the process does not automatically happen inside the deepCABAC decoder. Also, updating of the PUT comprises substituting the current values of the parameters (residuals or weight update) with the existing values in the PUT and updating their node depth values.

The PUT update process for the weight updates when encoded residuals are communicated is the same as the case when encoded weight updates are communicated, i.e. substituting the previous values with the current ones and updating the node depth, with the difference that this time, after deepCABAC decode, PRE decoder is called (not PRE encoder) to calculate weight updates given the residuals.

An outline of the updating process is as follows:
1. if encoded weight updates are communicated:
   a. deepCABAC decoder is called
      i. bitstream is decoded and weight updates are obtained
      ii. PUT of the weight updates is updated
         1. values of the weight updates in the PUT are updated with the newly computed values
         2. node_depths are updated accordingly
   b. PRE encoder is called to compute residuals
   c. PUT of the residuals is updated
      i. values of the residuals in the PUT are updated with the newly computed values
      ii. node_depths are updated accordingly
2. if encoded residuals are communicated:
   a. deepCABAC decoder is called
      i. bitstream is decoded and residuals are obtained
      ii. PUT of the residuals is updated
         1. values of the residuals in the PUT are updated with the newly computed values
         2. node_depths are updated accordingly
   b. PRE decoder is called to compute weight updates
   c. PUT of the weight updates is updated
      i. values of the weight updates in the PUT are updated with the newly computed values
      ii. node_depths are updated accordingly

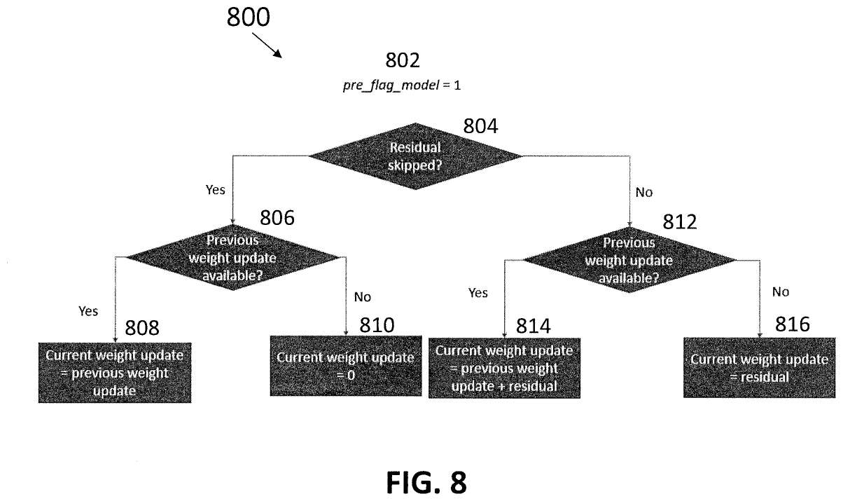

The procedure of computing the weight update value of a skipped parameter when the encoder has communicated the encoded residuals is shown in the flowchart 800 shown in FIG. 8. At 802, if pre_flag_model is 1 (i.e., if encoded residuals are communicated), then at 804a determination is made as to whether a residual is skipped. In response to a positive determination at 804 (e.g. “Yes”), the method transitions to 806. At 806, a determination is made as to whether a previous weight update is available. If at 806 it is determined that the previous weight update is available (e.g. “Yes”), the method transitions to 808. At 808, the current weight update is set to the previous weight update. If at 806 it is determined that the previous update is not available (e.g. “No”), the method transitions to 810. At 810, the current weight update is set to zero.

In response to a negative determination at 804 (e.g. “No”), the method transitions to 812. At 812, a determination is made as to whether a previous weight update is available. If at 812 it is determined that the previous weight update is available (e.g. “Yes”), the method transitions to 814. At 814, the current weight update is set to the previous weight update plus the residual. If at 812 it is determined that the previous update is not available (e.g. “No”), the method transitions to 816. At 816, the current weight update is set to be the residual.

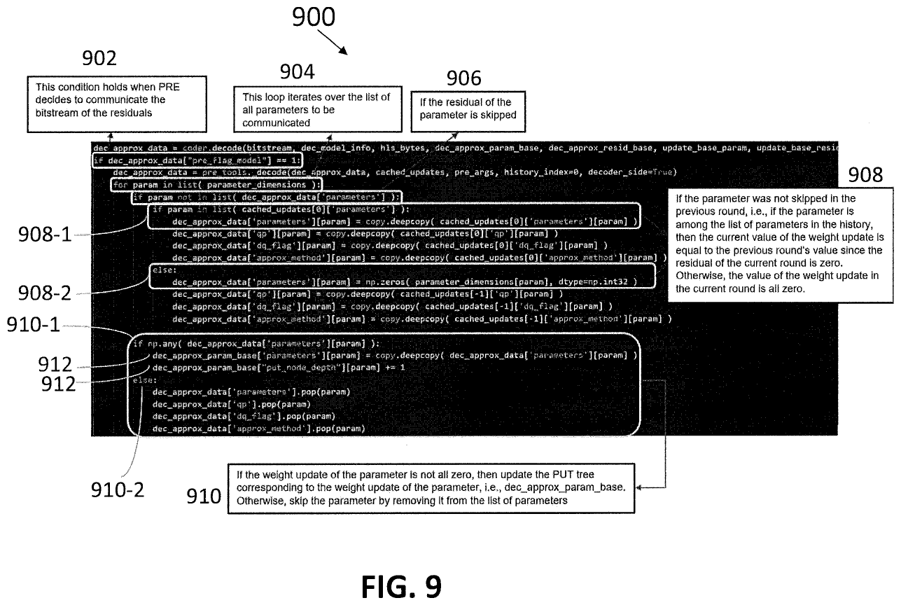

Also the code snippet 900 of the process 800 is shown in FIG. 9. Item 902 shows the condition that holds when PRE decides to communicate the bitstream of the residuals. Item 904 shows the loop that iterates over the list of all parameters to be communicated. Item 906 shows the statement that determines whether the residual of the parameter is skipped. Item 908 shows, if the parameter was not skipped in the previous round, i.e., if the parameter is among the list of parameters in the history, then the current value of the weight update is equal to the previous round's value (portion 908-1) since the residual of the current round is zero. Otherwise (else portion 908-2), the value of the weight update in the current round is zero. Item 910 shows, if the weight update of the parameter is not all zero (portion 910-1), then update the PUT tree corresponding to the weight update of the parameter, dec_approx_param_base 912. Otherwise (else portion 910-2), skip the parameter by removing it from the list of parameters using pop calls.

In an additional embodiment, where the encoding of the weight-update and/or of the residual may be lossy, the encoder may determine whether to communicate the encoded weight-update or the encoded residuals based at least on the bitrate of the encoded weight-update, on the bitrate of the encoded residual, on a performance value computed based at least on the decoded weight-update, and/or on a performance value computed based at least on the decoded residual. In one example, the encoder may compute a rate-distortion value for the case of communicating an encoded weight-update and a rate-distortion value for the case of communicating an encoded residual, and then communicate the encoded weight-update if its rate-distortion value is lower than the rate-distortion value of the encoded residual. In one example, the performance value may be computed based at least on the reconstruction accuracy of the weight-update and/or of the residual. In another example, the performance value may be computed based at least on the accuracy achieved by a neural network which is updated based on the encoded weight-update or the encoded residual, where the accuracy may be computed based at least on a validation dataset.

An alternative implementation could be using one PUT with meta-data corresponding to the type of data, i.e. the weight update or residual of current and past communications. After the decoding, the meta-data could be used to reconstruct the weight update corresponding to the current state by parsing the parameter update tree and employing the residuals until the last available weight update.

In an additional embodiment, the encoder may determine the context used to encode a weight update or a residual by the DeepCABAC. I.e., the encoder may determine a compression mode based on the compression performance from the combinations of the residual or weight update coding with the context of the previous residual or weight update retrieved from the corresponding PUT. The encoder may signal to the decoder the indicator of whether the residual or weight update coding is applied and the indicator of whether the previous residual or weight update retrieved from the corresponding PUT is used as the context for the DeepCABAC.

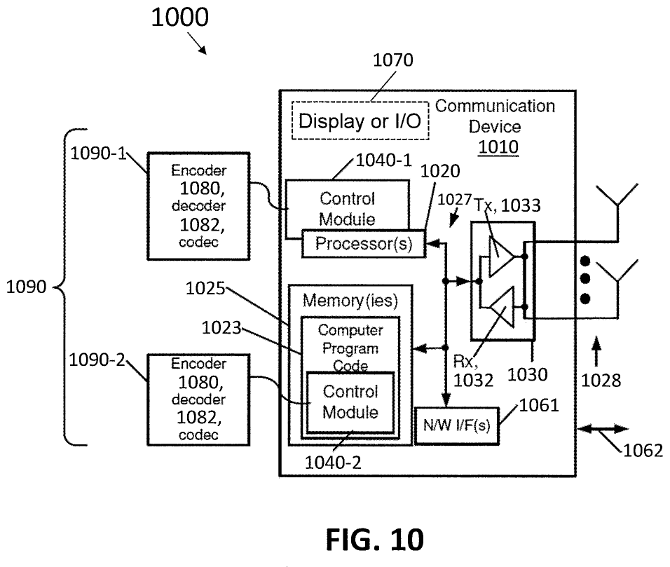

FIG. 10 is a block diagram 1000 of an apparatus 1010 suitable for implementing the exemplary embodiments. One nonlimiting example of the apparatus 1010 is a wireless, typically mobile device that can access a wireless network. The apparatus 1010 includes one or more processors 1020, one or more memories 1025, one or more transceivers 1030, and one or more network (N/W) interfaces (I/F(s)) 1061, interconnected through one or more buses 1027. Each of the one or more transceivers 1030 includes a receiver, Rx, 1032 and a transmitter, Tx, 1033. The one or more buses 1027 may be address, data, or control buses, and may include any interconnection mechanism, such as a series of lines on a motherboard or integrated circuit, fiber optics or other optical communication equipment, and the like.

The apparatus 1010 may communicate via wired, wireless, or both interfaces. For wireless communication, the one or more transceivers 1030 are connected to one or more antennas 1028. The one or more memories 1025 include computer program code 1023. The N/W I/F(s) 1061 communicate via one or more wired links 1062.

The apparatus 1010 includes a control module 1040, comprising one of or both parts 1040-1 and/or 1040-2, which include reference 1090 that includes encoder 1080, or decoder 1082, or a codec of both 1080/1082, and which may be implemented in a number of ways. For ease of reference, reference 1090 is referred to herein as a codec. The control module 1040 may be implemented in hardware as control module 1040-1, such as being implemented as part of the one or more processors 1020. The control module 1040-1 may be implemented also as an integrated circuit or through other hardware such as a programmable gate array. In another example, the control module 1040 may be implemented as control module 1040-2, which is implemented as computer program code 1023 and is executed by the one or more processors 1020. For instance, the one or more memories 1025 and the computer program code 1023 may be configured to, with the one or more processors 1020, cause the user equipment 1010 to perform one or more of the operations as described herein. The codec 1090 may be similarly implemented as codec 1090-1 as part of control module 1040-1, or as codec 1090-2 as part of control module 1040-2, or both.

The computer readable memories 1025 may be of any type suitable to the local technical environment and may be implemented using any suitable data storage technology, such as semiconductor-based memory devices, flash memory, firmware, magnetic memory devices and systems, optical memory devices and systems, fixed memory and removable memory. The computer readable memories 1025 may be means for performing storage functions. The computer readable one or more memories 1025 may be non-transitory, transitory, volatile (e.g. RAM) or non-volatile (e.g. ROM). The computer readable one or more memories 1025 may comprise a database for storing data.

The processors 1020 may be of any type suitable to the local technical environment, and may include one or more of general-purpose computers, special purpose computers, microprocessors, digital signal processors (DSPs) and processors based on a multi-core processor architecture, as non-limiting examples. The processors 1020 may be means for performing functions, such as controlling the apparatus 1010, and other functions as described herein.

In general, the various embodiments of the apparatus 1010 can include, but are not limited to, cellular telephones (such as smart phones, mobile phones, cellular phones, voice over Internet Protocol (IP) (VoIP) phones, and/or wireless local loop phones), tablets, portable computers, room audio equipment, immersive audio equipment, vehicles or vehicle-mounted devices for, e.g., wireless V2X (vehicle-to-everything) communication, image capture devices such as digital cameras, gaming devices, music storage and playback appliances, Internet appliances (including Internet of Things, IoT, devices), IoT devices with sensors and/or actuators for, e.g., automation applications, as well as portable units or terminals that incorporate combinations of such functions, laptops, laptop-embedded equipment (LEE), laptop-mounted equipment (LME), Universal Serial Bus (USB) dongles, smart devices, wireless customer-premises equipment (CPE), an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain context), a consumer electronics device, a device operating on commercial and/or industrial wireless networks, and the like. That is, the apparatus 1010 could be any device that may be capable of wireless or wired communication.

Thus, the apparatus 1010 comprises a processor 1020, at least one memory 1025 including computer program code 1023, wherein the at least one memory 1025 and the computer program code 1023 are configured to, with the at least one processor 1020, cause the apparatus 1010 to implement predictive residual encoding 1090 in neural network compression, based on the examples described herein. The apparatus 1010 optionally includes a display or I/O 1070 that may be used to display content during ML/task/machine/NN processing or rendering. Display or I/O 1070 may be configured to receive input from a user, such as with a keypad, touchscreen, touch area, microphone, biometric recognition etc. Apparatus 1010 may comprise standard well-known components such as an amplifier, filter, frequency-converter, and (de)modulator.

Computer program code 1023 may comprise object oriented software, and may implement the code snippets shown in FIG. 7 and FIG. 9, as well as the program flow shown in FIG. 8. The apparatus 1010 need not comprise each of the features mentioned, or may comprise other features as well. The apparatus 1010 may be an embodiment of apparatuses shown in FIG. 1, FIG. 2, FIG. 3, or FIG. 4, including any combination of those.

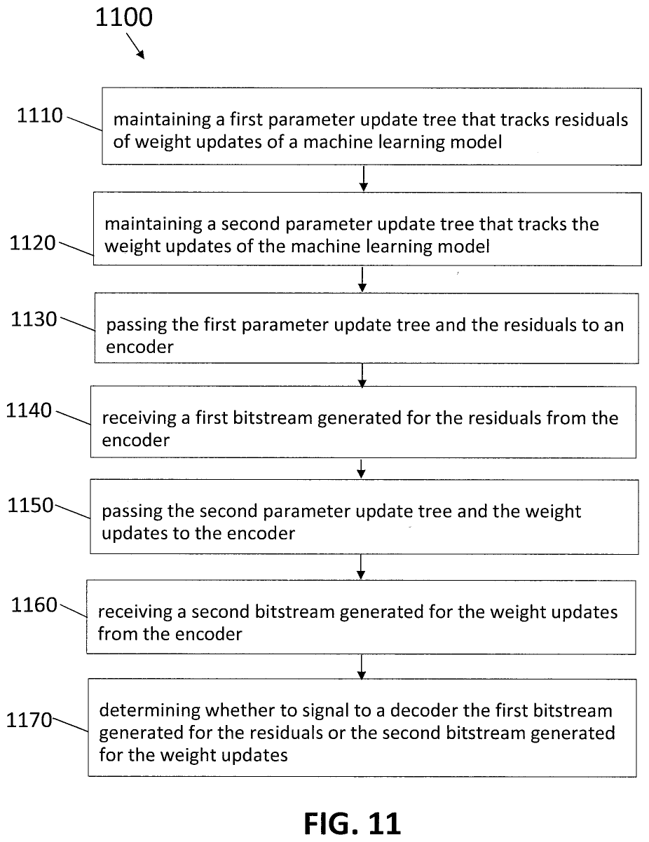

FIG. 11 is an example method 1100 to implement aspects of predictive residual encoding in neural network compression. At 1110, the method includes maintaining a first parameter update tree that tracks residuals of weight updates of a machine learning model. At 1120, the method includes maintaining a second parameter update tree that tracks the weight updates of the machine learning model. At 1130, the method includes passing the first parameter update tree and the residuals to an encoder. At 1140, the method includes receiving a first bitstream generated for the residuals from the encoder. At 1150, the method includes passing the second parameter update tree and the weight updates to the encoder. At 1160, the method includes receiving a second bitstream generated for the weight updates from the encoder. At 1170, the method includes determining whether to signal to a decoder the first bitstream generated for the residuals or the second bitstream generated for the weight updates. Method 1100 may be implemented by an encoder.

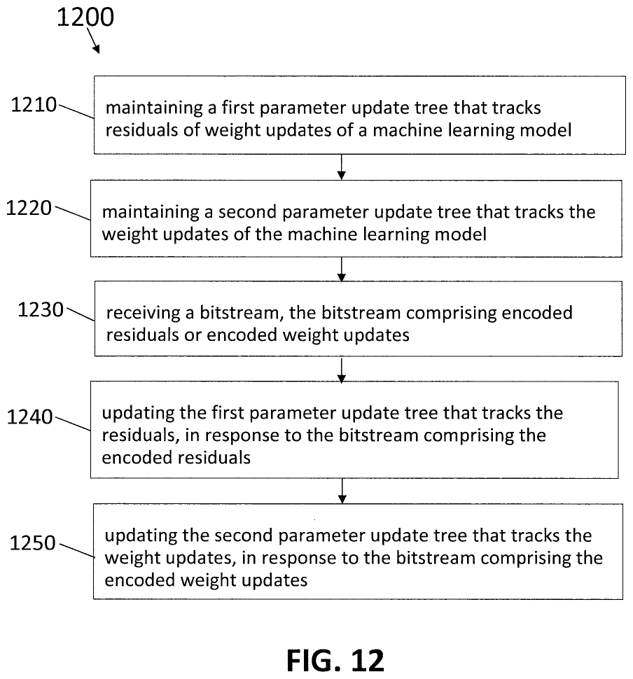

FIG. 12 is an example method 1200 to implement aspects of predictive residual encoding in neural network compression. At 1210, the method includes maintaining a first parameter update tree that tracks residuals of weight updates of a machine learning model. At 1220, the method includes maintaining a second parameter update tree that tracks the weight updates of the machine learning model. At 1230, the method includes receiving a bitstream, the bitstream comprising encoded residuals or encoded weight updates. At 1240, the method includes updating the first parameter update tree that tracks the residuals, in response to the bitstream comprising the encoded residuals. At 1250, the method includes updating the second parameter update tree that tracks the weight updates, in response to the bitstream comprising the encoded weight updates. Method 1200 may be implemented by a decoder.

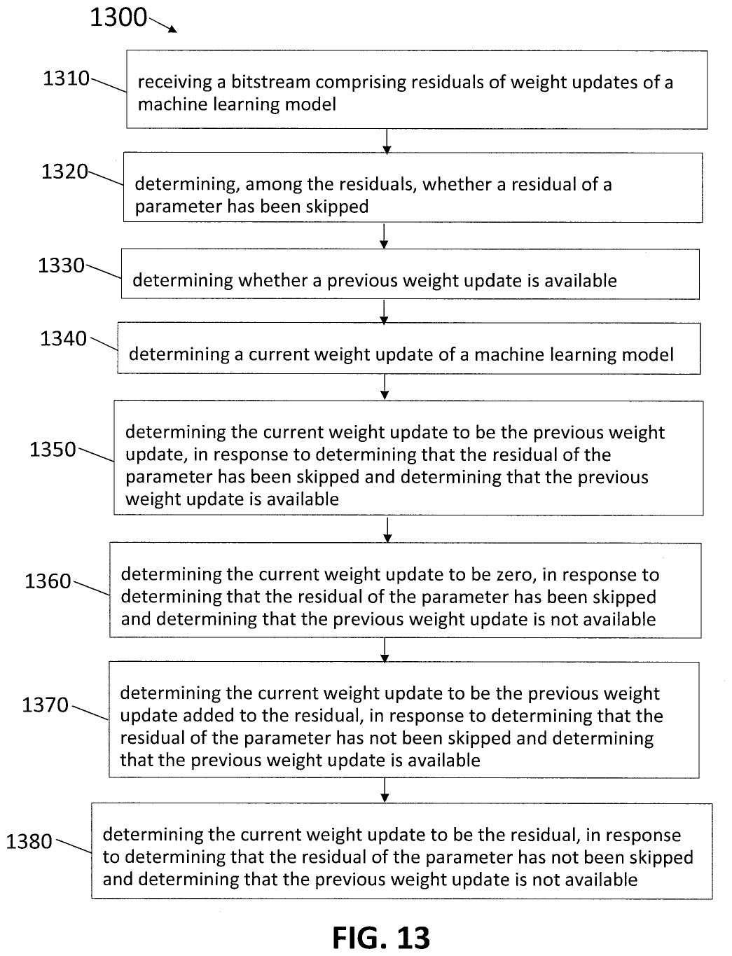

FIG. 13 is an example method 1300 to implement aspects of predictive residual encoding in neural network compression. At 1310, the method includes receiving a bitstream comprising residuals of weight updates of a machine learning model. At 1320, the method includes determining, among the residuals, whether a residual of a parameter has been skipped. At 1330, the method includes determining whether a previous weight update is available. At 1340, the method includes determining a current weight update of a machine learning model. At 1350, the method includes determining the current weight update to be the previous weight update, in response to determining that the residual of the parameter has been skipped and determining that the previous weight update is available. At 1360, the method includes determining the current weight update to be zero, in response to determining that the residual of the parameter has been skipped and determining that the previous weight update is not available. At 1370, the method includes determining the current weight update to be the previous weight update added to the residual, in response to determining that the residual of the parameter has not been skipped and determining that the previous weight update is available. At 1380, the method includes determining the current weight update to be the residual, in response to determining that the residual of the parameter has not been skipped and determining that the previous weight update is not available. Method 1300 may be implemented by a decoder.

References to a ‘computer’, ‘processor’, etc. should be understood to encompass not only computers having different architectures such as single/multi-processor architectures and sequential/parallel architectures but also specialized circuits such as field-programmable gate arrays (FPGAs), application specific circuits (ASICs), signal processing devices and other processing circuitry. References to computer program, instructions, code etc. should be understood to encompass software for a programmable processor or firmware such as, for example, the programmable content of a hardware device such as instructions for a processor, or configuration settings for a fixed-function device, gate array or programmable logic device, etc.

As used herein, the term ‘circuitry’, ‘circuit’ and variants may refer to any of the following: (a) hardware circuit implementations, such as implementations in analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. As a further example, as used herein, the term ‘circuitry’ would also cover an implementation of merely a processor (or multiple processors) or a portion of a processor and its (or their) accompanying software and/or firmware. The term ‘circuitry’ would also cover, for example and if applicable to the particular element, a baseband integrated circuit or applications processor integrated circuit for a mobile phone or a similar integrated circuit in a server, a cellular network device, or another network device. Circuitry or circuit may also be used to mean a function or a process used to execute a method.

The following examples (1-22) are described and provided herein.

Example 1: An apparatus includes at least one processor; and at least one memory including computer program code; wherein the at least one memory and the computer program code are configured to, with the at least one processor, cause the apparatus at least to: maintain a first parameter update tree that tracks residuals of weight updates of a machine learning model; maintain a second parameter update tree that tracks the weight updates of the machine learning model; pass the first parameter update tree and the residuals to an encoder; receive a first bitstream generated for the residuals from the encoder; pass the second parameter update tree and the weight updates to the encoder; receive a second bitstream generated for the weight updates from the encoder; and determine whether to signal to a decoder the first bitstream generated for the residuals or the second bitstream generated for the weight updates.

Example 2: The apparatus of example 1, wherein the at least one memory and the computer program code are further configured to, with the at least one processor, cause the apparatus at least to: compare a size of the first bitstream generated for the residuals to a size of the second bitstream generated for the weight updates; signal the first bitstream for the residuals to a decoder, in response to the first size being less than the second size; and signal the second bitstream generated for the weight updates to the decoder, in response to the second size being less than or equal to the first size.

Example 3: The apparatus of any of examples 1 to 2, wherein the at least one memory and the computer program code are further configured to, with the at least one processor, cause the apparatus at least to: define an encoding flag configured to signal the first bitstream or the second bitstream to the decoder; wherein the encoding flag comprises a value of 1 when the first bitstream for the residuals is signaled to the decoder, and the encoding flag comprises a value of 0 when the second bitstream for the weight updates is signaled to the decoder.

Example 4: The apparatus of any of examples 1 to 3, wherein the at least one memory and the computer program code are further configured to, with the at least one processor, cause the apparatus at least to: determine whether an encoded residual is lossy; determine whether an encoded weight update is lossy; and determine whether to signal to the decoder the first bitstream generated for the residuals or the second bitstream generated for the weight updates, when the encoded weight update and/or the encoded residual is lossy, based on at least one of: a first bitrate of the encoded residual; a second bitrate of the encoded weight update; a first performance value computed based at least on a decoded residual; or a second performance value computed based at least on a decoded weight update.

Example 5: The apparatus of any of examples 1 to 4, wherein the at least one memory and the computer program code are further configured to, with the at least one processor, cause the apparatus at least to: compute a first rate distortion value corresponding to an encoded residual; compute a second rate distortion value corresponding to an encoded weight update; signal the encoded residual, in response to the first rate distortion value being less than the second rate distortion value; and signal the encoded weight update, in response to the second rate distortion value being less than or equal to the first rate distortion value.

Example 6: The apparatus of any of examples 1 to 5, wherein the at least one memory and the computer program code are further configured to, with the at least one processor, cause the apparatus at least to: determine a first reconstruction accuracy of an encoded residual; determine a second reconstruction accuracy an encoded weight update; signal the encoded residual, in response to the first reconstruction accuracy being greater than the second reconstruction accuracy; and signal the encoded weight update, in response to the second reconstruction accuracy being greater than or equal to the first reconstruction accuracy.

Example 7: The apparatus of any of examples 1 to 6, wherein the at least one memory and the computer program code are further configured to, with the at least one processor, cause the apparatus at least to: determine a first accuracy of a neural network on a validation dataset based on an encoded residual; determine a second accuracy of the neural network on the validation dataset based on an encoded weight update; signal the encoded residual, in response to the first accuracy being greater than the second accuracy; and signal the encoded weight update, in response to the second accuracy being greater than the first accuracy.

Example 8: An apparatus includes at least one processor; and at least one memory including computer program code; wherein the at least one memory and the computer program code are configured to, with the at least one processor, cause the apparatus at least to: maintain a first parameter update tree that tracks residuals of weight updates of a machine learning model; maintain a second parameter update tree that tracks the weight updates of the machine learning model; receive a bitstream, the bitstream comprising encoded residuals or encoded weight updates; update the first parameter update tree that tracks the residuals, in response to the bitstream comprising the encoded residuals; and update the second parameter update tree that tracks the weight updates, in response to the bitstream comprising the encoded weight updates.

Example 9: The apparatus of example 8, wherein the at least one memory and the computer program code are further configured to, with the at least one processor, cause the apparatus at least to: define a decoding flag comprising a value based on an encoding flag received from an encoder; wherein the decoding flag comprises a value of 1 when the bitstream comprises the encoded residuals, and the decoding flag comprises a value of 0 when the bitstream comprises the encoded weight updates.

Example 10: The apparatus of any of examples 8 to 9, wherein the at least one memory and the computer program code are further configured to, with the at least one processor, cause the apparatus at least to: update the first parameter update tree that tracks the residuals with calling a predictive residual encoding encoder to calculate the residuals of the weight updates, in response to the bitstream comprising the encoded weight updates, due to the residuals not being available within a deep context-adaptive binary arithmetic coding decoder; and update the second parameter update tree that tracks the weight updates with calling a predictive residual encoding decoder to calculate the weight updates, in response to the bitstream comprising the encoded residuals, due to the weight updates not being available within the deep context-adaptive binary arithmetic coding decoder.

Example 11: The apparatus of any of examples 8 to 10, wherein the at least one memory and the computer program code are further configured to, with the at least one processor, cause the apparatus at least to: determine whether a residual of a parameter has been skipped, in response to the bitstream comprising the encoded residuals.

Example 12: The apparatus of example 11, wherein the at least one memory and the computer program code are further configured to, with the at least one processor, cause the apparatus at least to: determine whether a previous weight update is available, in response to determining that the residual of the parameter has been skipped; determine a current weight update to be a previous weight update, in response to determining that the previous weight update is available; and determine the current weight update to be zero, in response to determining that the previous weight update is not available.

Example 13: The apparatus of any of examples 11 to 12, wherein the at least one memory and the computer program code are further configured to, with the at least one processor, cause the apparatus at least to: determine whether a previous weight update is available, in response to determining that the residual of the parameter has not been skipped; determine a current weight update to be a previous weight update added to the residual, in response to determining that the previous weight update is available; and determine the current weight update to be the residual, in response to determining that the previous weight update is not available.

Example 14: The apparatus of any of examples 8 to 13, wherein the at least one memory and the computer program code are further configured to, with the at least one processor, cause the apparatus at least to: determine whether a weight update of a parameter is not all zero; update the second parameter update tree corresponding to the weight update of the parameter, in response to the weight update of the parameter being not all zero; and skip the parameter with removing the parameter from a list of parameters, in response to the weight update of the parameter being all zero.

Example 15: The apparatus of any of examples 12 to 14, wherein the at least one memory and the computer program code are further configured to, with the at least one processor, cause the apparatus at least to: loop over a set of parameters to determine the current weight update for the set of parameters.

Example 16: The apparatus of any of examples 8 to 15, wherein the at least one memory and the computer program code are further configured to, with the at least one processor, cause the apparatus at least to: maintain a parameter update tree with metadata corresponding to a type of data; wherein the type of data comprises at least one residual of current and past communications; wherein the type of data comprises at least one weight update of current and past communications; and reconstruct, using the metadata, the at least one weight update corresponding to a current state with parsing the parameter update tree and using the at least one residual until a last available weight update.

Example 17: A method includes maintaining a first parameter update tree that tracks residuals of weight updates of a machine learning model; maintaining a second parameter update tree that tracks the weight updates of the machine learning model; passing the first parameter update tree and the residuals to an encoder; receiving a first bitstream generated for the residuals from the encoder; passing the second parameter update tree and the weight updates to the encoder; receiving a second bitstream generated for the weight updates from the encoder; and determining whether to signal to a decoder the first bitstream generated for the residuals or the second bitstream generated for the weight updates.

Example 18: A method includes maintaining a first parameter update tree that tracks residuals of weight updates of a machine learning model; maintaining a second parameter update tree that tracks the weight updates of the machine learning model; receiving a bitstream, the bitstream comprising encoded residuals or encoded weight updates; updating the first parameter update tree that tracks the residuals, in response to the bitstream comprising the encoded residuals; and updating the second parameter update tree that tracks the weight updates, in response to the bitstream comprising the encoded weight updates.

Example 19: An apparatus includes means for maintaining a first parameter update tree that tracks residuals of weight updates of a machine learning model; means for maintaining a second parameter update tree that tracks the weight updates of the machine learning model; means for passing the first parameter update tree and the residuals to an encoder; means for receiving a first bitstream generated for the residuals from the encoder; means for passing the second parameter update tree and the weight updates to the encoder; means for receiving a second bitstream generated for the weight updates from the encoder; and means for determining whether to signal to a decoder the first bitstream generated for the residuals or the second bitstream generated for the weight updates.

Example 20: An apparatus includes means for maintaining a first parameter update tree that tracks residuals of weight updates of a machine learning model; means for maintaining a second parameter update tree that tracks the weight updates of the machine learning model; means for receiving a bitstream, the bitstream comprising encoded residuals or encoded weight updates; means for updating the first parameter update tree that tracks the residuals, in response to the bitstream comprising the encoded residuals; and means for updating the second parameter update tree that tracks the weight updates, in response to the bitstream comprising the encoded weight updates.

Example 21: A non-transitory program storage device readable by a machine, tangibly embodying a program of instructions executable with the machine for performing operations, the operations comprising: maintaining a first parameter update tree that tracks residuals of weight updates of a machine learning model; maintaining a second parameter update tree that tracks the weight updates of the machine learning model; passing the first parameter update tree and the residuals to an encoder; receiving a first bitstream generated for the residuals from the encoder; passing the second parameter update tree and the weight updates to the encoder; receiving a second bitstream generated for the weight updates from the encoder; and determining whether to signal to a decoder the first bitstream generated for the residuals or the second bitstream generated for the weight updates.

Example 22: A non-transitory program storage device readable by a machine, tangibly embodying a program of instructions executable with the machine for performing operations, the operations comprising: maintaining a first parameter update tree that tracks residuals of weight updates of a machine learning model; maintaining a second parameter update tree that tracks the weight updates of the machine learning model; receiving a bitstream, the bitstream comprising encoded residuals or encoded weight updates;

updating the first parameter update tree that tracks the residuals, in response to the bitstream comprising the encoded residuals; and updating the second parameter update tree that tracks the weight updates, in response to the bitstream comprising the encoded weight updates.

In the figures, arrows between individual blocks represent operational couplings there-between as well as the direction of data flows on those couplings.

It should be understood that the foregoing description is only illustrative. Various alternatives and modifications may be devised by those skilled in the art. For example, features recited in the various dependent claims could be combined with each other in any suitable combination(s). In addition, features from different embodiments described above could be selectively combined into a new embodiment. Accordingly, the description is intended to embrace all such alternatives, modifications and variances which fall within the scope of the appended claims.

The following acronyms and abbreviations that may be found in the specification and/or the drawing figures are defined as follows:
3GPP 3rd generation partnership project
4G fourth generation of broadband cellular network technology
5G fifth generation cellular network technology
802.x family of IEEE standards dealing with local area networks and metropolitan area networks
ASIC application specific integrated circuit
CABAC context-adaptive binary arithmetic coding
CDMA code-division multiple access
CfP call for proposal
CPE customer premises equipment
DCT discrete cosine transform
DSP digital signal processor
FDMA frequency division multiple access
FI federated inference
FL federated learning
FPGA field programmable gate array
GSM global system for mobile communications
H.222.0 MPEG-2 systems, standard for the generic coding of moving pictures and associated audio information
H.26x family of video coding standards in the domain of the ITU-T
HMD head mounted display
IBC intra block copy
IEC International Electrotechnical Commission
IEEE Institute of Electrical and Electronics
Engineers
I/F interface
IMD integrated messaging device
IMS instant messaging service
I/O input output
IoT internet of things
IP internet protocol
ISO International Organization for Standardization
ISOBMFF ISO base media file format
ITU International Telecommunication Union
ITU-T ITU Telecommunication Standardization Sector
LEE laptop embedded equipment
LME laptop-mounted equipment
LTE long-term evolution
ML machine learning
MMS multimedia messaging service
MPEG moving picture experts group
MPEG-2 H.222/H.262 as defined by the ITU
MSE mean squared error
NAL network abstraction layer
NN neural network
NNC neural network compression
N/W network
PC personal computer
PDA personal digital assistant
PID packet identifier
PLC power line communication
PRE predictive residual encoding
PUT parameter update tree
RFID radio frequency identification
RFM reference frame memory
Rx receiver
SMS short messaging service
TCA temporal context adaptation
TCP-IP transmission control protocol-internet protocol
TDMA time divisional multiple access
TS transport stream
TV television
Tx transmitter
UICC universal integrated circuit card
UMTS universal mobile telecommunications system
USB universal serial bus
V2X vehicle-to-everything
VoIP voice over IP
VVC versatile video codec
WLAN wireless local area network

What is claimed is:

1. An apparatus comprising:
at least one processor; and
at least one memory storing instructions that, when executed by the at least one processor, cause the apparatus at least to:
maintain a first parameter update tree that tracks residuals of weight updates of a machine learning model;
maintain a second parameter update tree that tracks the weight updates of the machine learning model;
pass the first parameter update tree and the residuals to an encoder;
receive a first bitstream generated for the residuals from the encoder;
pass the second parameter update tree and the weight updates to the encoder;
receive a second bitstream generated for the weight updates from the encoder; and
determine whether to signal to a decoder the first bitstream generated for the residuals or the second bitstream generated for the weight updates.

2. The apparatus of claim 1, wherein the instructions, when executed by the at least one processor, cause the apparatus at least to:
compare a size of the first bitstream generated for the residuals to a size of the second bitstream generated for the weight updates;
signal the first bitstream for the residuals to a decoder, in response to the first size being less than the second size; and
signal the second bitstream generated for the weight updates to the decoder, in response to the second size being less than or equal to the first size.

3. The apparatus of claim 1, wherein the instructions, when executed by the at least one processor, cause the apparatus at least to:
define an encoding flag configured to signal the first bitstream or the second bitstream to the decoder;
wherein the encoding flag comprises a value of 1 when the first bitstream for the residuals is signaled to the decoder, and the encoding flag comprises a value of 0 when the second bitstream for the weight updates is signaled to the decoder.

4. The apparatus of claim 1, wherein the instructions, when executed by the at least one processor, cause the apparatus at least to:
determine whether an encoded residual is lossy;
determine whether an encoded weight update is lossy; and
determine whether to signal to the decoder the first bitstream generated for the residuals or the second bitstream generated for the weight updates, when the encoded weight update and/or the encoded residual is lossy, based on at least one of:
a first bitrate of the encoded residual;
a second bitrate of the encoded weight update;
a first performance value computed based at least on a decoded residual; or
a second performance value computed based at least on a decoded weight update.

5. The apparatus of claim 1, wherein the instructions, when executed by the at least one processor, cause the apparatus at least to:
compute a first rate distortion value corresponding to an encoded residual;
compute a second rate distortion value corresponding to an encoded weight update;
signal the encoded residual, in response to the first rate distortion value being less than the second rate distortion value; and
signal the encoded weight update, in response to the second rate distortion value being less than or equal to the first rate distortion value.

6. The apparatus of claim 1, wherein the instructions, when executed by the at least one processor, cause the apparatus at least to:
determine a first reconstruction accuracy of an encoded residual;
determine a second reconstruction accuracy an encoded weight update;
signal the encoded residual, in response to the first reconstruction accuracy being greater than the second reconstruction accuracy; and
signal the encoded weight update, in response to the second reconstruction accuracy being greater than or equal to the first reconstruction accuracy.

7. The apparatus of claim 1, wherein the instructions, when executed by the at least one processor, cause the apparatus at least to:
determine a first accuracy of a neural network on a validation dataset based on an encoded residual;
determine a second accuracy of the neural network on the validation dataset based on an encoded weight update;
signal the encoded residual, in response to the first accuracy being greater than the second accuracy; and
signal the encoded weight update, in response to the second accuracy being greater than the first accuracy.

8. An apparatus comprising:
at least one processor; and
at least one memory storing instructions that, when executed by the at least one processor, cause the apparatus at least to:
maintain a first parameter update tree that tracks residuals of weight updates of a machine learning model;
maintain a second parameter update tree that tracks the weight updates of the machine learning model;
receive a bitstream, the bitstream comprising encoded residuals or encoded weight updates;
update the first parameter update tree that tracks the residuals, in response to the bitstream comprising the encoded residuals; and
update the second parameter update tree that tracks the weight updates, in response to the bitstream comprising the encoded weight updates.

9. The apparatus of claim 8, wherein the instructions, when executed by the at least one processor, cause the apparatus at least to:
define a decoding flag comprising a value based on an encoding flag received from an encoder;
wherein the decoding flag comprises a value of 1 when the bitstream comprises the encoded residuals, and the decoding flag comprises a value of 0 when the bitstream comprises the encoded weight updates.

10. The apparatus of claim 8, wherein the instructions, when executed by the at least one processor, cause the apparatus at least to:
update the first parameter update tree that tracks the residuals with calling a predictive residual encoding encoder to calculate the residuals of the weight updates, in response to the bitstream comprising the encoded weight updates, due to the residuals not being available within a deep context-adaptive binary arithmetic coding decoder; and
update the second parameter update tree that tracks the weight updates with calling a predictive residual encoding decoder to calculate the weight updates, in response to the bitstream comprising the encoded residuals, due to the weight updates not being available within the deep context-adaptive binary arithmetic coding decoder.

11. The apparatus of claim 8, wherein the instructions, when executed by the at least one processor, cause the apparatus at least to:
determine whether a residual of a parameter has been skipped, in response to the bitstream comprising the encoded residuals.

12. The apparatus of claim 11, wherein the instructions, when executed by the at least one processor, cause the apparatus at least to:
determine whether a previous weight update is available, in response to determining that the residual of the parameter has been skipped;
determine a current weight update to be a previous weight update, in response to determining that the previous weight update is available; and
determine the current weight update to be zero, in response to determining that the previous weight update is not available.

13. The apparatus of claim 11, wherein the instructions, when executed by the at least one processor, cause the apparatus at least to:
determine whether a previous weight update is available, in response to determining that the residual of the parameter has not been skipped;
determine a current weight update to be a previous weight update added to the residual, in response to determining that the previous weight update is available; and
determine the current weight update to be the residual, in response to determining that the previous weight update is not available.

14. The apparatus of claim 8, wherein the instructions, when executed by the at least one processor, cause the apparatus at least to:
determine whether a weight update of a parameter is not all zero;
update the second parameter update tree corresponding to the weight update of the parameter, in response to the weight update of the parameter being not all zero; and
skip the parameter with removing the parameter from a list of parameters, in response to the weight update of the parameter being all zero.

15. The apparatus of claim 12, wherein the instructions, when executed by the at least one processor, cause the apparatus at least to:
loop over a set of parameters to determine the current weight update for the set of parameters.

16. The apparatus of claim 8, wherein the instructions, when executed by the at least one processor, cause the apparatus at least to:
maintain a parameter update tree with metadata corresponding to a type of data;
wherein the type of data comprises at least one residual of current and past communications;
wherein the type of data comprises at least one weight update of current and past communications; and
reconstruct, using the metadata, the at least one weight update corresponding to a current state with parsing the parameter update tree and using the at least one residual until a last available weight update.

17. A method comprising:
maintaining a first parameter update tree that tracks residuals of weight updates of a machine learning model;
maintaining a second parameter update tree that tracks the weight updates of the machine learning model;
passing the first parameter update tree and the residuals to an encoder;
receiving a first bitstream generated for the residuals from the encoder;
passing the second parameter update tree and the weight updates to the encoder;
receiving a second bitstream generated for the weight updates from the encoder; and
determining whether to signal to a decoder the first bitstream generated for the residuals or the second bitstream generated for the weight updates.

18. The method of claim 17, further comprising:
comparing a size of the first bitstream generated for the residuals to a size of the second bitstream generated for the weight updates;
signaling the first bitstream for the residuals to a decoder, in response to the first size being less than the second size; and
signaling the second bitstream generated for the weight updates to the decoder, in response to the second size being less than or equal to the first size.

19. The method of claim 17, further comprising:
defining an encoding flag configured to signal the first bitstream or the second bitstream to the decoder;
wherein the encoding flag comprises a value of 1 when the first bitstream for the residuals is signaled to the decoder, and the encoding flag comprises a value of 0 when the second bitstream for the weight updates is signaled to the decoder.

20. The method of claim 17, further comprising:
determining whether an encoded residual is lossy;
determining whether an encoded weight update is lossy; and
determining whether to signal to the decoder the first bitstream generated for the residuals or the second bitstream generated for the weight updates, when the encoded weight update and/or the encoded residual is lossy, based on at least one of:
a first bitrate of the encoded residual;
a second bitrate of the encoded weight update;
a first performance value computed based at least on a decoded residual; or
a second performance value computed based at least on a decoded weight update.
